(19) United States
(12) Patent Application Publication
(10) Pub. No.: US 2020/0051994 A1
(43) Pub. Date: Feb. 13, 2020

(54) MEMORY DEVICE IMPROVEMENT

(71) Applicant: Applied Materials, Inc., Santa Clara, CA (US)

(72) Inventors: Vinod Robert PURAYATH, Cupertino, CA (US); Priyadarshi PANDA, Newark, CA (US); Abhijit MALLICK, Fremont, CA (US); Srinivas GANDIKOTA, Santa Clara, CA (US)

(21) Appl. No.: 16/150,652

(22) Filed: Oct. 3, 2018

Related U.S. Application Data
(60) Provisional application No. 62/717,582, filed on Aug. 10, 2018.

(51) Int. Cl. H01L 27/11582; H01L 27/1157; H01L 27/11524; H01L 27/11556

(52) U.S. Cl. CPC H01L 27/11582; H01L 27/11556; H01L 27/11524; H01L 27/1157

(57) ABSTRACT

A method of forming a memory device including a plurality of nonvolatile memory cells is provided. The method includes forming a hole in a stack of alternating insulator layers and memory cell layers. The stack extends from a bottom to a top, and the stack includes a plurality of insulator layers and plurality of memory cell layers. The method further includes depositing a first portion of a silicon channel layer. The first portion of the silicon channel layer extends from the bottom of the stack to the top of the stack. The method further includes adding a dopant layer over the first portion of the silicon channel layer. The dopant layer includes a first dopant. The method further includes depositing a second portion of the silicon channel layer. The second portion of the silicon channel layer extends from the bottom of the stack to the top of the stack.

### CROSS-REFERENCE TO RELATED APPLICATIONS

This application claims benefit of U.S. provisional patent application Ser. No. 62/717,582, filed Aug. 10, 2018, which is hereby incorporated herein by reference.

### BACKGROUND

### Field

Embodiments of the present disclosure generally relate to transistors, for example transistors used in memory, and methods of forming transistors including methods for forming the channels of the transistors.

### Description of the Related Art

Transistor speed is a key factor to consider when designing many electronic devices. For example, transistor speed affects how fast processors can operate and how fast memory can be stored and retrieved. One feature of a transistor that effects the overall speed of the transistor is carrier mobility through the channel of the transistor. Carrier mobility is how fast an electron or hole can move through a material (e.g., semiconductor) when an electric field is applied. Thus, the higher the carrier mobility, the faster the transistor can operate, such as transistor used in 3-D NAND memory.

3-D NAND memory uses floating gate transistors that generally include a silicon channel, such as a polysilicon channel. Polysilicon is a material that offers high carrier mobility, but the carrier mobility of polysilicon can be inhibited by the crystal grain boundaries present in the polycrystalline structure of polysilicon. One solution is to form monocrystalline silicon, but processes, such as epitaxy, that are used to form monocrystalline silicon are generally too slow and expensive to be used for the mass production of memory for electronic devices.

Therefore, there is a need for an improved transistor and method for forming an improved transistor that results in higher carrier mobility than transistors including conventional polysilicon channels.

### SUMMARY

Embodiments of the present disclosure generally relate to a 3-D NAND memory device and methods of forming the 3-D NAND memory device.

In one embodiment, a method of forming a memory device including a plurality of nonvolatile memory cells is provided. The method includes forming a hole in a stack of alternating insulator layers and memory cell layers to expose an edge surface of each layer in the stack. The stack extends from a bottom to a top, and the stack includes a plurality of insulator layers and plurality of memory cell layers between the bottom and the top of the stack. The method further includes depositing a first portion of a silicon channel layer, wherein the first portion of the silicon channel layer extends from the bottom of the stack to the top of the stack; adding a dopant layer over the first portion of the silicon channel layer, wherein the dopant layer includes a first dopant; and depositing a second portion of the silicon channel layer, and wherein the second portion of the silicon channel layer extends from the bottom of the stack to the top of the stack.

In another embodiment, a method of forming a memory device including a plurality of nonvolatile memory cells. The method includes forming a hole in a stack of alternating insulator layers and memory cell layers to expose an edge surface of each layer in the stack, wherein the stack extends from a bottom to a top, and the stack includes a plurality of insulator layers and plurality of memory cell layers between the bottom and the top of the stack. The method further includes depositing a first portion of a silicon channel layer, wherein the first portion of the silicon channel layer extends from the bottom of the stack to the top of the stack; depositing a second portion of the silicon channel layer, wherein the second portion of the silicon channel layer extends from the bottom of the stack to the top of the stack; heating the silicon channel layer to transform the silicon channel layer into a polysilicon channel layer; and reducing the thickness of the polysilicon channel layer by at least 10% until a target thickness of the polysilicon layer is reached.

In another embodiment, a 3-D flash memory device is provided. The 3-D flash memory device includes a plurality of memory cells arranged in a stack, wherein the stack is formed over a substrate and each memory cell in the stack is separated from other memory cells in the stack in a vertical direction, each memory cell comprising: a charge trap flash layer; a polysilicon channel layer doped with a first dopant; and a gate oxide disposed between the channel layer and the charge trap flash layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic cross-sectional view of a portion of a 3-D NAND memory device, according to one embodiment of the disclosure.

FIG. 2 is a process flow diagram of a method 1000 of forming the 3-D NAND memory device shown in FIG. 1, according to one embodiment.

FIGS. 3A-3J are schematic cross-sectional views of the 3-D NAND memory device of FIG. 1 at different stages of the production described in the method of FIG. 2, according to one embodiment.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

Embodiments of the present disclosure generally relate to a 3-D NAND memory device and methods of forming the 3-D NAND memory device. The 3-D NAND memory device includes a polysilicon channel that is doped with a p-type dopant, such as boron or germanium. The dopant is added to an amorphous silicon layer, and then the doped amorphous silicon layer is annealed to crystallize the layer into a doped polysilicon layer that can be used as the channel for a transistor, such as a transistor of a memory cell in a 3-D NAND memory device. The dopant added to the amorphous silicon layer results in a polysilicon layer that has a lower number of crystal grain boundaries and a larger average crystal grain size relative to a similarly formed layer of undoped polysilicon that would include a larger number of crystal grain boundaries having a smaller average crystal grain size. Having a smaller number of larger crystal grain boundaries on average can result in a polysilicon channel layer (i.e., the doped polysilicon layer) having a higher carrier mobility relative to the similarly formed undoped polysilicon layer. For example, in some embodiments the dopant can cause the average grain size to be more than two times or three times the size of the average grain size of the similarly formed undoped polysilicon layer.

Furthermore, in some embodiments, the polysilicon channel layer can be initially formed at an enlarged thickness that is then subsequently reduced, for example by at least 10%, to a target thickness after crystallization, which also results in an increase in carrier mobility for the polysilicon channel layer relative to a similarly formed polysilicon channel layer that is initially formed to have the target thickness without any subsequent reduction in thickness. The higher carrier mobility of the initially thicker polysilicon channel layer having a thickness that is subsequently reduced is also due to a decrease in total crystal grain boundaries that have a larger average crystal grain size relative to a polysilicon channel layer that is formed to have the same final thickness without any thickness reduction because the polysilicon channel layer formed without any thickness reduction results in a larger number of crystal grain boundaries having a smaller average crystal grain size than the initially thicker polysilicon layer that has a thickness that is reduced after crystallization.

Although the following description describes embodiments of 3-D NAND memory devices that include transistors of memory cells having polysilicon channel layers with increased carrier mobility, the description is also applicable to increasing the carrier mobility of the channel layers of other transistors. Furthermore although the following description describes doping channel layers with boron and germanium, the description is also applicable to doping channel layers with other p-type dopants or with n-type dopants to obtain similar benefits for other p-type channel layers and n-type channel layers respectively.

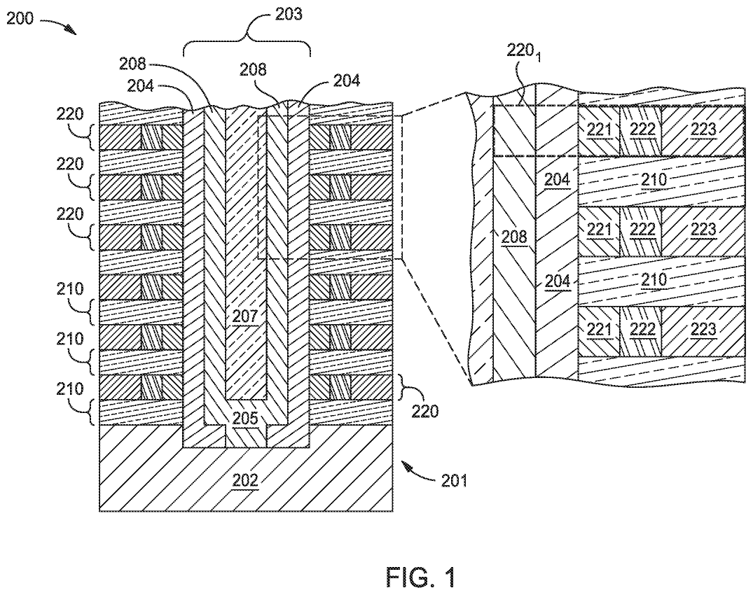

FIG. 1 shows a schematic cross-sectional view of a portion of a 3-D NAND memory device 200, according to an embodiment. The 3-D NAND memory device 200 is a Bit Cost Scalable (BiCS) device, and includes a string 201 of vertically stacked memory cells 220 formed on a semiconductor substrate 202. The string 201 of vertically stacked memory cells 220 includes a plurality of memory cells 220 alternately disposed between a plurality of insulator layers 210. As shown, the insulator layers 210 and the memory cells 220 are formed around a memory hole 203, in which a gate oxide layer 204, a polysilicon channel layer 208, and an optional filler material 207 are disposed. The memory device 200 further includes a plurality of select gates coupled to word lines (not shown) and another plurality of select gates coupled to bit lines (not shown) so that memory can be stored and retrieved from each memory cell in the memory device 200. “Top,” “up,” and “upward” are used herein to describe elements or directions perpendicularly distal from the plane of the semiconductor substrate 202 and the center of mass of the semiconductor substrate 202. Similarly, “vertical” is used to describe elements or directions aligned in the “upward” direction, i.e., towards the “top”.

The semiconductor substrate 202 may be any suitable starting material for forming integrated circuits, such as a silicon (Si) wafer or a germanium (Ge) wafer. The semiconductor substrate 202 may be a silicon semiconductor substrate having a layer or layers formed thereon, such as a film stack, employed to form a structure on the semiconductor substrate 202, such as the 3-D NAND memory device 200. The semiconductor substrate 202 may include a material such as crystalline silicon (e.g., Si<100> or Si<111>), silicon oxide, strained silicon, silicon germanium, doped or undoped polysilicon, doped or undoped silicon, patterned or non-patterned wafer, silicon on insulator (SOI), carbon-doped silicon oxides, silicon nitride, doped silicon, germanium, gallium arsenide, glass, sapphire, metal layers disposed on silicon, and the like. The semiconductor substrate 202 may be configured to have various sizes and shapes, such as a 200 mm, 300 mm, or 450 mm diameter wafer, or a rectangular or square panel.

The isolator layers 210 are disposed between and electrically isolate the memory cells 220 from each other. Furthermore, the isolator layers 210 may be any suitable electrically isolating material, such as a TEOS-formed silicon dioxide.

Each of memory cells 220 corresponds to part of a word line of the 3-D NAND memory device 200, each word line extending into the page to connect to additional memory cells 220 (not shown) of the 3-D NAND memory device 200. Each memory cell 220 is configured to store one or more bits of data. As such, each memory cell 220 includes a charge trap layer 221, a blocking oxide 222, and a control gate 223 as well as a portion of the gate oxide layer 204 that contacts the charge trap layer 221 of the memory cell 220 and a portion of the polysilicon channel layer 208 that contacts that portion of the gate oxide layer 204. For example, an exemplary first memory cell 220₁ is shown by the area enclosed by the dashed box 220₁ shown in FIG. 1.

The charge trap layer 221 is the charge storage region of the memory cell 220 that is used for memory storage. Although each memory cell 220 includes an individual charge trap layer 221, in other embodiments, a single charge trap layer can be used for a plurality of memory cells, and particular regions of the single charge trap layer can be used to store memory for individual memory cells. According to embodiments of the disclosure, each charge trap layer 221 can be formed of a material suitable for storing charge, such as a silicon nitride (Si₃N₄) layer.

The blocking oxide 222 generally includes a material that prevents or reduces diffusion of metal atoms from control gate 223 into the gate oxide 204 while also isolating the control gate 223 from the charge trap layer 221. The control gate 223 for a given memory cell 220 can include a conductive material (e.g., a metallic material) that is configured to enable a particular voltage to be applied proximate the charge trap layer 221 of the given memory cell 220 when writing to or reading from the given memory cell 220.

The gate oxide layer 204 is disposed between the charge trap layer 221 of a memory cell 220 and the portion of the polysilicon channel layer 208 for that memory cell 220. The gate oxide layer 208 can be formed of a suitable dielectric material, such as silicon dioxide. The 3-D NAND memory device 200 can store memory using the individual memory cells 220 shown in FIG. 1. For example, charge from the polysilicon channel layer 208 can be transferred between the polysilicon channel layer 208 and the charge trap layer 221 to store data in the charge trap layer 221 of a given memory cell 220.

The polysilicon channel layer 208 is a conductive structure that can provide and accept charge (e.g., electrons) to and from the charge trap layer 221 of each memory cell 220 for memory storage. For example, in some embodiments, the polysilicon channel layer 208 includes a doped polysilicon material, such as a polysilicon layer doped with boron or germanium. In one embodiment, the polysilicon channel layer 208 is doped with boron, and the boron concentration can be from about 0.5% and about 45%, such as from about 1% and about 30%. In another embodiment, the polysilicon channel layer 208 is doped with germanium, and the germanium concentration can be from about 0.5% and about 45%, such as from about 1% and about 30%, such as from about 1.5% to about 15%.

Doping the polysilicon channel layer 208 increases the carrier mobility of the polysilicon channel layer 208 relative to a similarly formed undoped polysilicon channel layer. For example, the dopant (e.g., boron or germanium) in the polysilicon layer 208 results in a polysilicon layer 208 that has a lower number of crystal grain boundaries and a larger average crystal grain size relative to a similarly formed layer of undoped polysilicon that would include a larger number of crystal grain boundaries and a smaller average crystal grain size. Having a smaller number of larger crystal grain boundaries on average results in a polysilicon channel layer (i.e., the doped polysilicon layer) having a higher carrier mobility relative to the similarly formed undoped polysilicon layer having a larger number of crystal grain boundaries and a smaller average crystal grain size.

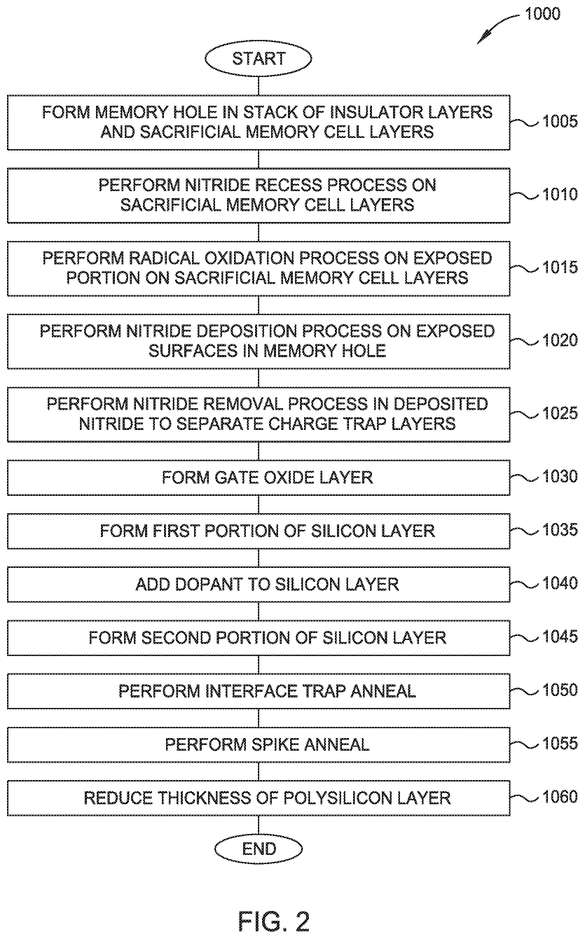

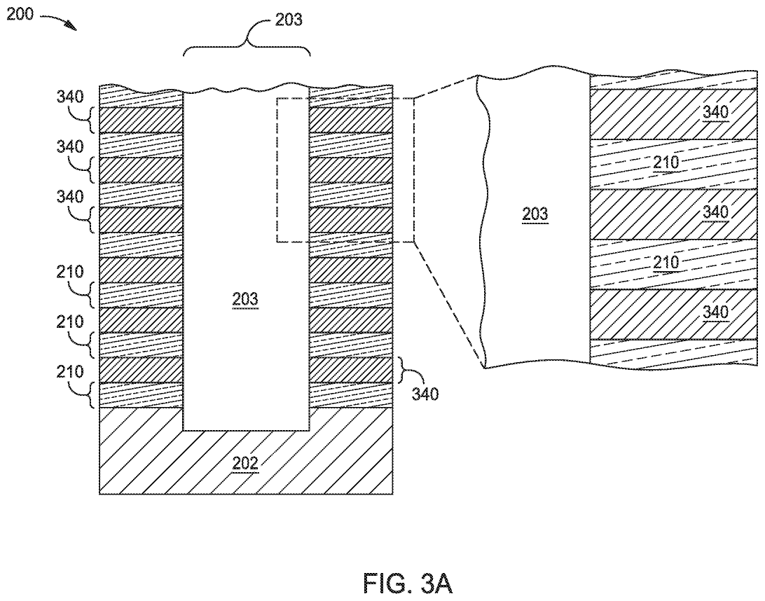

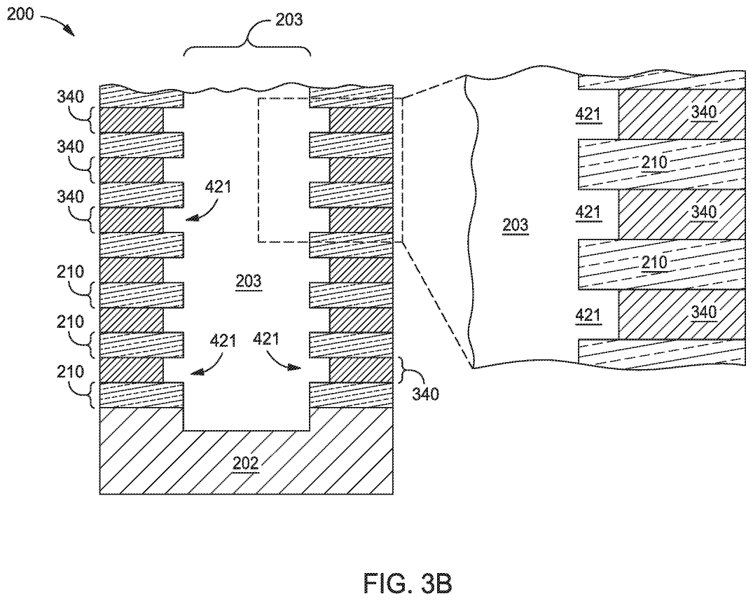

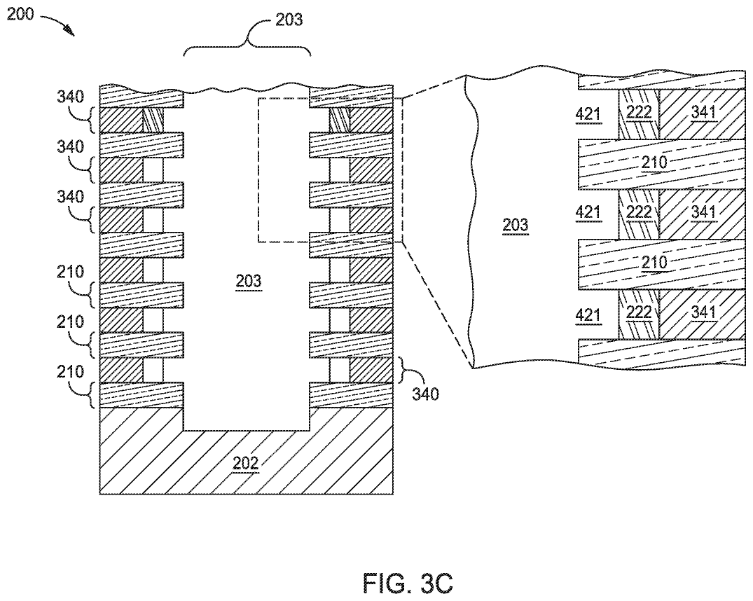

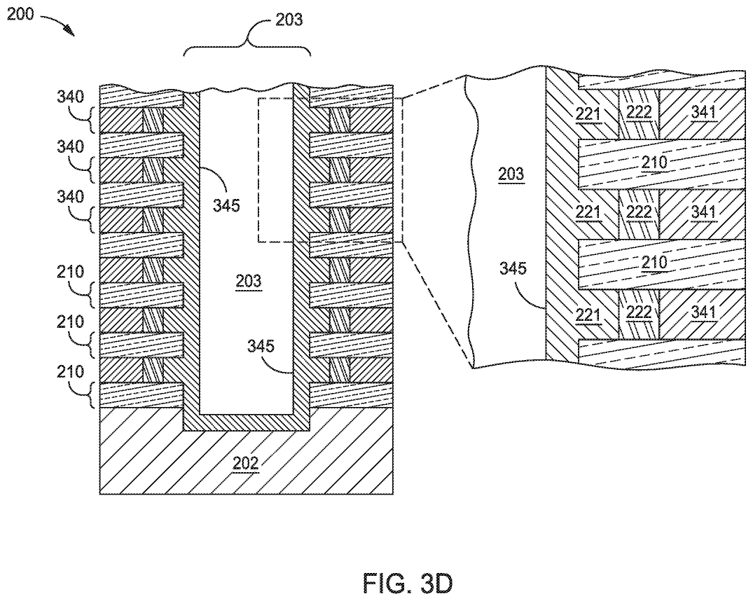

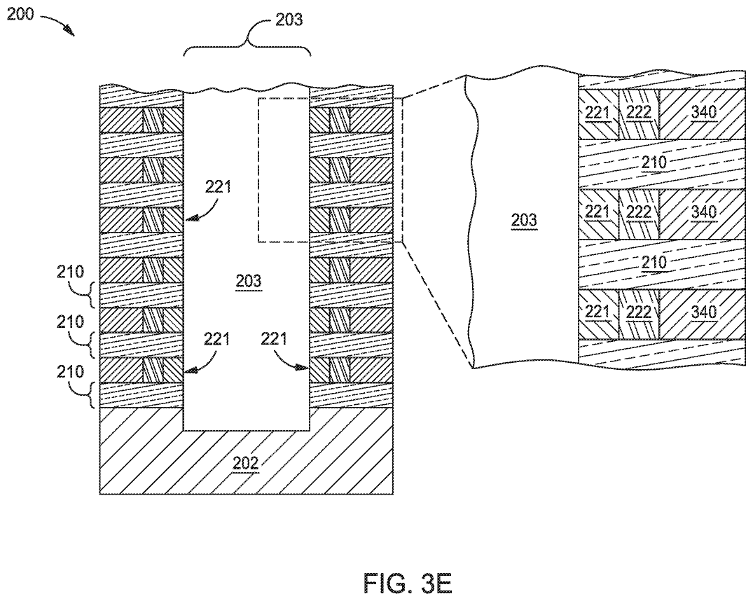

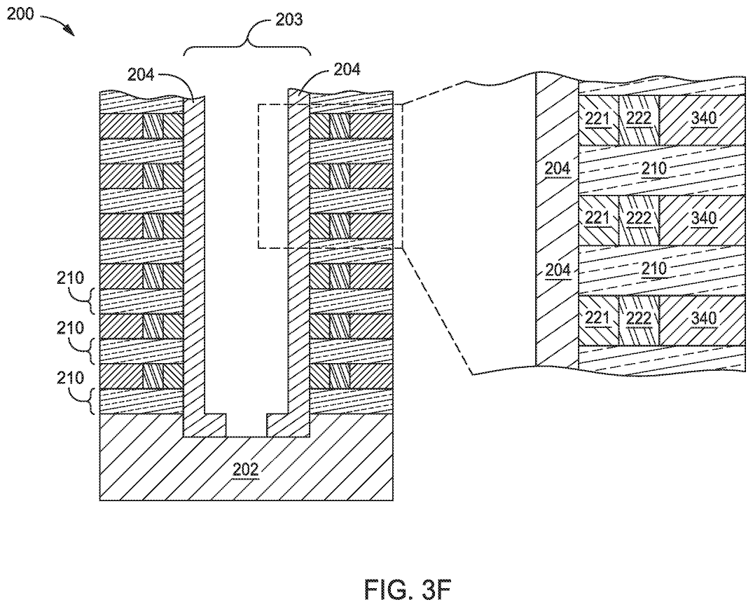

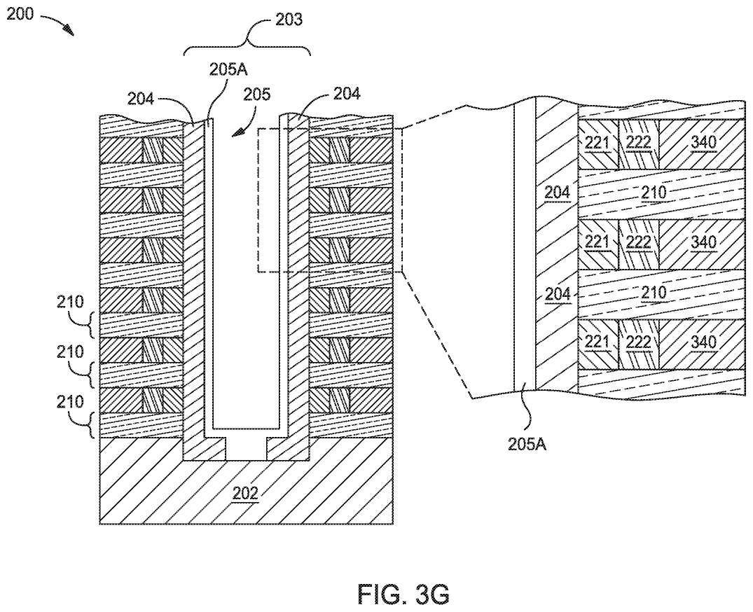

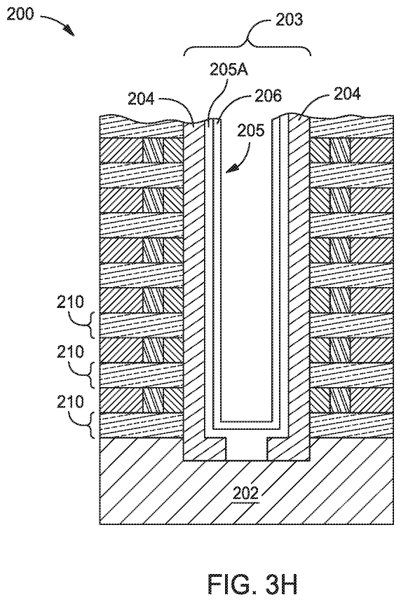

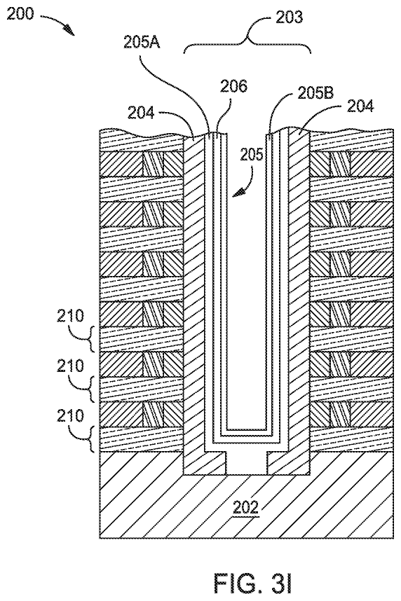

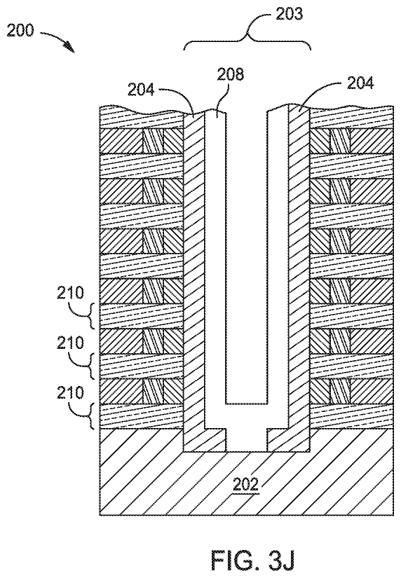

FIG. 2 is a process flow diagram of a method 1000 of forming the 3-D NAND memory device 200 shown in FIG. 1, according to one embodiment. FIGS. 3A-3I are schematic cross-sectional views of the 3-D NAND memory device 200 at different stages of the production described in the method 1000 of FIG. 2, according to one embodiment.

The method 1000 begins at block 1005, in which the memory hole 203 is formed in a stack of alternating insulator layers 210 and sacrificial memory cell layers 340 deposited on the semiconductor substrate 202, as shown in FIG. 3A. Any suitable etching method may be employed to form the memory hole 203, such as deep reactive-ion etching (DRIE), a highly anisotropic etch process employed to create high aspect-ratio holes and trenches on layers formed on wafers or other substrates. In some embodiments, the sacrificial memory cell layers 340 are Si₃N₄ layers and the insulating layers 210 can be silicon dioxide.

At block 1010, a nitride recess process is performed to remove an exposed portion of the sacrificial memory cell layers 340 to form cavities 421, as shown in FIG. 3B. The nitride recess process of block 1010 is performed on edge surfaces of the insulator layers 210 and the sacrificial memory cell layers 340 that are exposed to memory hole 203. Generally any isotropic etch process that is selective against at least the material of insulator layers 210 may be employed in block 1010 to remove a portion of sacrificial memory cell layers 340 with high selectivity. For example, in some embodiments, a portion of sacrificial memory cell layers 340 is removed with a reactive species that is formed via a remote plasma from a process gas comprising oxygen (O₂) and nitrogen trifluoride (NF₃). More specifically, a fluorine-containing precursor and, in some embodiments, an oxygen-containing precursor are flowed into a remote plasma region while striking a plasma to form plasma effluents that then flow through a showerhead into a substrate processing region housing semiconductor substrate 202. Highly selective dry etching processes that may be used for the removal of Si₃N₄ layers in this way are described in U.S. Pat. No. 9,165,786, entitled “Integrated oxide and nitride recess for better channel contact in 3-D architectures” and filed Aug. 5, 2014.

Generally, the quantity of Si₃N₄ material removed at block 1010 is sufficient for creating the space for the subsequent formation of the isolated charge trap layers 221 for each memory cell 220, as shown in FIG. 1. Thus, the voids formed by the cavities 421 at block 1010 are substantially the same size as the subsequently formed charge trap layers 221 for each memory cell 220.

The nitride recessing process of block 1010 may be performed in a suitable etch chamber that is configured to selectively remove a portion of the sacrificial memory cell layers 340, such as the Selectra™ process chamber, available from Applied Materials, Inc. of Santa Clara, Calif., and the like. In particular, an etch chamber configured with a dual channel showerhead can enable an etching process that allows for separation of etchants outside of the processing region, which provides limited interaction with chamber components and each other prior to being delivered into the processing region. The etch chamber employed in block 1010 may be a standalone chamber, or part of a cluster tool, such as one of the ENDURA® line of cluster tools, also available from Applied Materials, Inc.

At block 1015, a radical oxidation process is performed to form blocking oxides 222 by oxidizing an exposed portion of the sacrificial memory cell layers 340, as shown in FIG. 3C. Generally, any isotropic oxidation process suitable for uniformly oxidizing the sacrificial memory cell layers 340 for each memory cell 220 of 3-D NAND memory device 200 can be employed at block 1010. For example, in some embodiments, portions of the sacrificial memory cell layers 340 are converted to blocking oxide 222 with a reactive species that is formed via a remote plasma. One such radical oxidation process is described in U.S. Patent Application 2011/0061812, entitled “Apparatus and Methods for Cyclical Oxidation and Etching” and filed Mar. 10, 2010. Generally, the quantity of Si₃N₄ converted to the blocking oxide 222 is determined based on what thickness of the blocking oxide 222 is suitable for the specific materials employed in memory cells 220 and the process temperatures employed in forming the same. Upon completion of block 1015, a portion of the sacrificial memory cell layers 340 are converted to the blocking oxide 222 and a remainder portion 341 of sacrificial memory cell layers 340 remains disposed between the insulator layers 210.

The radical oxidation process of block 1015 may be performed in any suitable deposition chamber, such as the Decoupled Plasma Oxidation (DPO) reactors available from Applied Materials, Inc., of Santa Clara, Calif., or the like. The deposition chamber employed at block 1015 may be a standalone chamber, or part of a cluster tool, such as one of a Gate Stack CENTURA®, available from Applied Materials, Inc., of Santa Clara, Calif.

At block 1020, a nitride deposition process is performed on exposed surfaces within memory hole 203 to form a Si₃N₄ layer 345, as shown in FIG. 3-D. The charge trap layers 221 of the memory cells 220 are formed by this nitride deposition process when cavities 421 (shown in FIG. 3C) are filled with the Si₃N₄ layer 345. Generally, any nitride deposition process suitable for filling cavities 421 in sacrificial memory cell layers 340 for each memory cell 220 may be employed at block 1020.

At block 1025, a nitride removal process is performed to remove a portion of Si₃N₄ layer 345 and separate charge trap layers 221 from each other, as shown in FIG. 3E. In some embodiments, the nitride removal process of block 1025 may be substantially similar to the nitride etch process employed at block 1010. In some embodiments, the nitride etch process of block 1025 is modified with respect to the nitride etch process of block 1010 to have a significantly slower etch rate and provide finer thickness control. Upon completion of block 1025, the charge trap layers 221 for the separate memory cells 220 are physically and electrically separated from each other.

At block 1030, the gate oxide layer 204 is deposited on exposed surfaces of charge trap layers 221 and the insulator layers 210, as shown in FIG. 3F. The gate oxide 204 can be formed of a dielectric material, such as silicon dioxide.

At block 1035, a first portion 205A of an amorphous silicon layer 205 is deposited on exposed surfaces of the gate oxide layer 204 as shown in FIG. 3G. Conventional amorphous silicon deposition techniques may be employed to form the first portion 205A of the amorphous silicon layer 205. For example, in one embodiment, the first portion 205A of the amorphous silicon layer 205 is deposited using a chemical vapor deposition (CVD) process, a low pressure CVD (LPCVD), or a plasma enhanced CVD (PECVD). In one such embodiment, a silicon source, such as silane or disilane can be provided to a LPCVD chamber to enable deposition of the first portion 205A of the amorphous silicon layer 205. The amorphous silicon layer 205 is eventually converted to a polysilicon channel layer 208 (see FIG. 3J) through one or more annealing processes as described below.

At block 1040, a dopant is added to the amorphous silicon layer 205 forming a dopant layer 206 over the first portion 205A of the amorphous silicon layer 205 as shown in FIG. 3H. Although dopant layer 206 is shown as a separate layer from the first portion 205A, in some embodiments, the dopant layer 206 can include dopant implanted into the first portion 205A as well as a separate layer deposited on top of the first portion 205A.

In one embodiment, the dopant is boron. The dopant layer 206 of boron can be deposited on the first portion 205A of the amorphous silicon layer 205. The boron can be deposited using conventional deposition techniques. The dopant layer 206 of boron can be deposited using CVD, LPCVD, or PECVD, for example by using a boron gas source, such as diborane. Additionally, in some embodiments, the dopant layer 206 of boron can be deposited using the same chamber that was used to deposit the first portion 205A of the amorphous silicon layer 205. Furthermore, in some embodiments, the dopant layer 206 of boron can be deposited at the same time as some of the first portion 205A is deposited. For example, in one embodiment, a silicon source (e.g., silane) and a boron source (diborane) can be provided to a CVD chamber, LPCVD chamber, or a PECVD chamber at the same time. Furthermore, in some embodiments, the boron concentration after all of the silicon is deposited (including the second portion 205B described below) can be from about 0.5% and about 45%, such as from about 1% and about 30%.

In another embodiment, the dopant is germanium. The germanium can be implanted into a top portion of the first portion 205A of the amorphous silicon layer 205 forming the dopant layer 206. The germanium can be implanted using conventional implant techniques, such as plasma assisted doping (PLAD). The dopant layer 206 of germanium can be implanted using PLAD, for example by using a germanium gas source, such as germane (GeH₄). In some embodiments, hydrogen gas (H₂) can be supplied with the germane (GeH₄) during the implant process.

In some embodiments, the 3-D NAND memory device 200 is transferred from the chamber (e.g., an LPCVD chamber) used to deposit the first portion 205A of the amorphous silicon layer 205 to an implant chamber. In some embodiments, a dry preclean can be performed on the device 200 before the implant of germanium is performed to remove any accumulation of any oxides or moisture that can occur during transfer of the device 200 between chambers. For example, in one embodiment, a SICONI® etch can be performed. In one such embodiment, NF₃ and NH₃ plasma byproducts can be used to perform a largely conformal SICONI® etch.

At block 1045, a second portion 205B of the amorphous silicon layer 205 is deposited over the dopant layer 206 as shown in FIG. 3I. Conventional silicon deposition techniques may be employed to form the second portion 205B of the amorphous silicon layer 205. For example, in some embodiments, the same process (e.g., CVD, LPCVD, or PECVD) used to deposit the first portion 205A of the amorphous silicon layer 205 can be used to deposit the second portion 205B of the amorphous silicon layer 205.

In some embodiments, the total thickness of the amorphous silicon layer 205 (including the first portion 205A and the second portion 205B and the dopant layer 206) can be from about 25 Å to be about 200 Å, such as from about 50 Å to about 100 Å. Furthermore, in some embodiments, the dopant layer 206 can have a thickness from about 2 Å to be about 40 Å, such as from about 5 Å to about 20 Å.

At block 1050, an interface trap anneal is performed on the device 200. The interface trap anneal can be performed using conventional annealing techniques. In some embodiments, the memory device 200 can be annealed at a temperature from about 700° C. to about 900° C., such as about 850° C. for a duration from about 15 minutes to about 2 hours, such as from about 30 minutes to about 1 hour. During the interface trap anneal, the dopant (e.g., boron or germanium) can be distributed throughout the first portion 205A and the second portion 205B of the amorphous silicon layer 205.

The interface trap anneal can also cause impurities (e.g., hydrogen, fluorine, or other atoms) to migrate to the exposed surface of the polysilicon layer 208. In some embodiments, an anneal in the presence of hydrogen can be performed after the interface anneal at block 1050 and before the spike anneal process described below in reference to block 1055. This hydrogen anneal can help remove the impurities that accumulate near the exposed surface of the polysilicon layer 208. For example, in one embodiment, a forming gas of hydrogen and nitrogen is supplied to an annealing chamber that is heated from about 350° C. to about 450° C. The hydrogen concentration in the forming gas can be from about 2% to about 7%, such as from about 3% to about 5%. In another embodiment, a hydrogen plasma at a temperature from about 250° C. to about 300° C. can be used to remove the impurities that accumulate near the exposed surface of the polysilicon layer 208.

At block 1055, a spike anneal is performed on the device 200. The spike anneal can be performed using conventional annealing techniques. The spike anneal process can be used to quickly heat the amorphous silicon layer 205 to transform the amorphous silicon layer 205 into a polysilicon channel layer 208 as shown in FIG. 3J. For example, in one embodiment the amorphous silicon layer 205 is heated to from about 950° C. to about 1150° C., such as to about 1050° C., for a duration from about 2 seconds to about 20 seconds, such as from about 5 seconds to about 10 seconds. Furthermore, in some embodiments, the spike anneal is performed in the absence of oxygen to prevent oxidation of silicon in the polysilicon channel layer 205.

The polysilicon channel layer 208 is a layer formed of many crystals of silicon. The presence of the dopant (e.g., boron or germanium) can help increase the average crystal grain size and reduce the total number of crystal grain boundaries relative to forming a similar polysilicon channel layer without a dopant. This reduction in the total number of crystal grain boundaries results in increased carrier mobility through the polysilicon channel layer 208 relative to a polysilicon layer having a higher number of crystal grain boundaries.

At block 1060, a thickness reduction can be performed on the polysilicon channel layer 208. Average crystal grain size is noted to increase with the thickness of a polysilicon layer. This increase in average crystal grain size for a thicker polysilicon layer can also result in a decrease in the total number of crystal grain boundaries for a given volume of a polysilicon layer relative to a total number of crystal grain boundaries of a thinner polysilicon layer. Thus, the number of crystal grain boundaries in a polysilicon layer having a target thickness can be reduced by initially forming a polysilicon layer having a thickness greater than the target thickness and then reducing the thickness to the target thickness relative to simply forming the polysilicon layer to have the target thickness without any removal of polysilicon. As noted above, a reduction in the number of crystal grain boundaries can result in increased carrier mobility even if the average crystal grain size increases. Thus, the thickness reduction performed at block 1060 can also be used to increase carrier mobility through the polysilicon channel layer.

Although not shown, the remaining portions of the sacrificial memory cell layers 340 can be removed, for example using a nitride strip process, such as a process substantially similar to the nitride etch process employed in block 1010. Upon completion of the removal of the remaining portions of the sacrificial memory cell layers 340, the cavities created by the removal can be subsequently filled to form control gates 223 (see FIG. 1) of memory cells 220. The control gates 223 can be formed via a metal deposition process, for example via a chemical-vapor deposition (CVD) or atomic-layer deposition (ALD) process,

While the foregoing is directed to embodiments of the present disclosure, other and further embodiments of the disclosure may be devised without departing from the basic scope thereof, and the scope thereof is determined by the claims that follow.

1. A method of forming a memory device including a plurality of nonvolatile memory cells, the method comprising:
forming a hole in a stack of alternating insulator layers and memory cell layers to expose an edge surface of each layer in the stack, wherein
the stack extends from a bottom to a top, and
the stack includes a plurality of insulator layers and plurality of memory cell layers between the bottom and the top of the stack;
depositing a first portion of a silicon channel layer, wherein the first portion of the silicon channel layer extends from the bottom of the stack to the top of the stack;
adding a dopant layer over the first portion of the silicon channel layer, wherein the dopant layer includes a first dopant; and
depositing a second portion of the silicon channel layer, wherein the second portion of the silicon channel layer extends from the bottom of the stack to the top of the stack.

2. The method of claim 1, further comprising heating the silicon channel layer to transform the silicon channel layer into a polysilicon channel layer.

3. The method of claim 1, wherein the first dopant is boron.

4. The method of claim 1, wherein the first dopant is germanium.

5. The method of claim 2, wherein an average grain size of the polysilicon channel layer is at least twice as large as an average grain size of a similarly formed undoped polysilicon channel layer.

6. The method of claim 2, wherein a total number of crystal grain boundaries of the polysilicon channel layer is at least 10% less than a total number of crystal grain boundaries of a similarly formed undoped polysilicon channel layer.

7. The method of claim 2, further comprising reducing the thickness of the polysilicon channel layer by at least 10%.

8. The method of claim 2, wherein
each memory cell includes at least a portion of a charge trap flash layer,
the method further comprises forming a gate oxide layer, and
the gate oxide layer is disposed between polysilicon channel layer and the charge trap flash layer.

9. The method of claim 8, wherein the charge trap flash layer is formed of silicon nitride (Si₃N₄).

10. A method of forming a memory device including a plurality of nonvolatile memory cells, the method comprising:
forming a hole in a stack of alternating insulator layers and memory cell layers to expose an edge surface of each layer in the stack, wherein
the stack extends from a bottom to a top, and
the stack includes a plurality of insulator layers and plurality of memory cell layers between the bottom and the top of the stack;
depositing a first portion of a silicon channel layer, wherein the first portion of the silicon channel layer extends from the bottom of the stack to the top of the stack;
depositing a second portion of the silicon channel layer, wherein the second portion of the silicon channel layer extends from the bottom of the stack to the top of the stack; and
heating the silicon channel layer to transform the silicon channel layer into a polysilicon channel layer; and
reducing the thickness of the polysilicon channel layer by at least 10% until a target thickness of the polysilicon layer is reached.

11. The method of claim 10, wherein an average crystal grain size of the polysilicon channel layer that is reduced to the target thickness is at least 25% larger than an average crystal grain size of a similarly formed polysilicon channel layer that is initially formed to have the target thickness without any reduction in thickness after forming the similarly formed polysilicon channel layer.

12. The method of claim 10, wherein a total number of crystal grain boundaries of the polysilicon channel layer that is reduced to the target thickness is at least 10% less than a total number of crystal grain boundaries of a similarly formed polysilicon channel layer that is initially formed to have the target thickness without any reduction in thickness after forming the similarly formed polysilicon channel layer.

13. The method of claim 10, wherein
each memory cell includes at least a portion of a charge trap flash layer,
the method further comprises forming a gate oxide layer, and
the gate oxide layer is disposed between polysilicon channel layer and the charge trap flash layer.

14. The method of claim 13, wherein the charge trap flash layer is formed of silicon nitride (Si₃N₄).

15. The method of claim 10, further comprising adding a dopant layer over the first portion of the silicon channel layer, wherein the dopant layer includes a first dopant.

16. The method of claim 15, wherein the first dopant is boron or germanium.

17. A 3-D flash memory device comprising:
a plurality of memory cells arranged in a stack, wherein the stack is formed over a substrate and each memory cell in the stack is separated from other memory cells in the stack in a vertical direction, each memory cell comprising:
a charge trap flash layer;
a polysilicon channel layer doped with a first dopant; and
a gate oxide disposed between the channel layer and the charge trap flash layer.

18. The 3-D flash memory device of claim 17, wherein the charge trap flash layer is formed of silicon nitride (Si₃N₄).

19. The 3-D flash memory device of claim 17, wherein the first dopant is boron.

20. The 3-D flash memory device of claim 17, wherein the first dopant is germanium.
